(19) United States
(12) Patent Application Publication
(10) Pub. No.: US 2024/0404878 A1
(43) Pub. Date: Dec. 5, 2024

(54) SEMICONDUCTOR DEVICES AND METHODS OF MANUFACTURING SEMICONDUCTOR DEVICES

(71) Applicant: Amkor Technology Portugal, S.A., Vila do Conde (PT)

(72) Inventor: Eoin O'Toole, Porto (PT)

(21) Appl. No.: 18/326,304

(22) Filed: May 31, 2023

(51) Int. Cl. H01L 21/768; H01L 21/56; H01L 23/00; H01L 23/31; H01L 23/498; H01L 23/528

(52) U.S. Cl. CPC H01L 21/76873; H01L 21/565; H01L 23/3128; H01L 23/49822; H01L 23/528; H01L 24/16; H01L 2224/16225; H01L 2924/186

(57) ABSTRACT

An electronic device comprises a substrate and a semiconductor component coupled to the substrate. The substrate may include a dielectric layer, a seed layer, a conductive pattern, and an external interconnect first structure coupled to the conductive pattern. The dielectric layer may include photo-definable dielectric material. The conductive pattern and the external interconnect first structure may include one or more electroplated conductive layers formed using the same seed layer of the substrate.

### BACKGROUND

Present semiconductor packages and methods of forming semiconductor packages are inadequate, for example resulting in excess cost, decreased reliability, or package sizes that are too large. Further limitations and disadvantages of conventional and traditional approaches will become apparent to one of skill in the art, through comparison of such approaches with the present disclosure as set forth in the remainder of the present application with reference to the drawings.

### BRIEF DESCRIPTION OF SEVERAL VIEWS OF THE DRAWINGS

FIG. 1 depicts a cross-section of an example electronic device.

FIG. 2 depicts a flowchart for an example method of making the electronic device of FIG. 1.

FIGS. 3A-3E show cross-sectional views illustrating an example subpanel manufacturing process for the method of FIG. 2.

FIGS. 4A-4F show cross-sectional views illustrating another example subpanel manufacturing process for the method of FIG. 2.

FIGS. 5A-5F depict examples of panels for the method FIG. 2.

FIGS. 6A and 6B depict a panel manufacturing process for the method of FIG. 2.

FIGS. 7A-7H show cross-sectional views illustrating example panel processing for the method of FIG. 2

FIGS. 8A-8C show cross-sectional views illustrating example subpanel processing for the method of FIG. 2

### SUMMARY

Various aspects of this disclosure relate to an electronic device having a photo-definable and/or low loss tangent dielectric layer and a seed layer from which multiple conductive structures (e.g., conductive pattern(s), conductive stud(s), etc.) are formed. Various aspects of this disclosure further relate to a system for manufacturing such electronic devices per a manufacturing method that forms the electronic devices from panels comprising multiple subpanels having multiple semiconductor components. The manufacturing method may include performing various operations on multiple subpanels and their respective semiconductor components while mounted to a carrier panel, and perform additional operations on a subpanel after it has been removed from the carrier panel. As such, aspects of the manufacturing method may be performed at a panel level and other aspects of the manufacturing method may be performed at a subsequent subpanel level.

### DETAILED DESCRIPTION OF VARIOUS ASPECTS OF THE DISCLOSURE

The following discussion presents various aspects of the present disclosure by providing examples thereof. Such examples are non-limiting, and thus the scope of various aspects of the present disclosure should not necessarily be limited by any particular characteristics of the provided examples. In the following discussion, the phrases “for example,” “e.g.,” and “exemplary” are non-limiting and are generally synonymous with “by way of example and not limitation,” “for example and not limitation,” and the like.

As utilized herein, “and/or” means any one or more of the items in the list joined by “and/or”. As an example, “x and/or y” means any element of the three-element set {(x), (y), (x, y)}. In other words, “x and/or y” means “one or both of x and y.” As another example, “x, y, and/or z” means any element of the seven-element set {(x), (y), (z), (x, y), (x, z), (y, z), (x, y, z)}. In other words, “x, y and/or z” means “one or more of x, y, and z.” Similarly, as utilized herein, “or” means any one or more of the items in the list joined by “or”.

The terminology used herein is for the purpose of describing particular examples only and is not intended to be limiting of the disclosure. As used herein, the singular forms are intended to include the plural forms as well, unless the context clearly indicates otherwise. It will be further understood that the terms “comprises,” “includes,” “comprising,” “including,” “has,” “have,” “having,” and the like when used in this specification, specify the presence of stated features, integers, steps, operations, elements, or components, but do not preclude the presence or addition of one or more other features, integers, steps, operations, elements, components, or groups thereof.

It will be understood that, although the terms first, second, etc. may be used herein to describe various elements, these elements should not be limited by these terms. These terms are only used to distinguish one element from another element. Thus, for example, a first element, a first component or a first section discussed below could be termed a second element, a second component or a second section without departing from the teachings of the present disclosure. Similarly, various spatial terms, such as “upper,” “lower,” “lateral,” “side,” “top,” “bottom,” and the like, may be used in distinguishing one element from another element in a relative manner. It should be understood, however, that components may be oriented in different manners, for example a semiconductor component or package may be turned sideways so that its “top” surface is facing horizontally and its “lateral” or “side” surface is facing vertically, without departing from the teachings of the present disclosure.

Various aspects of the present disclosure are directed to semiconductor components and fabricating or manufacturing methods thereof, which may decrease the cost, increase the reliability, and/or increase the manufacturability of such semiconductor components.

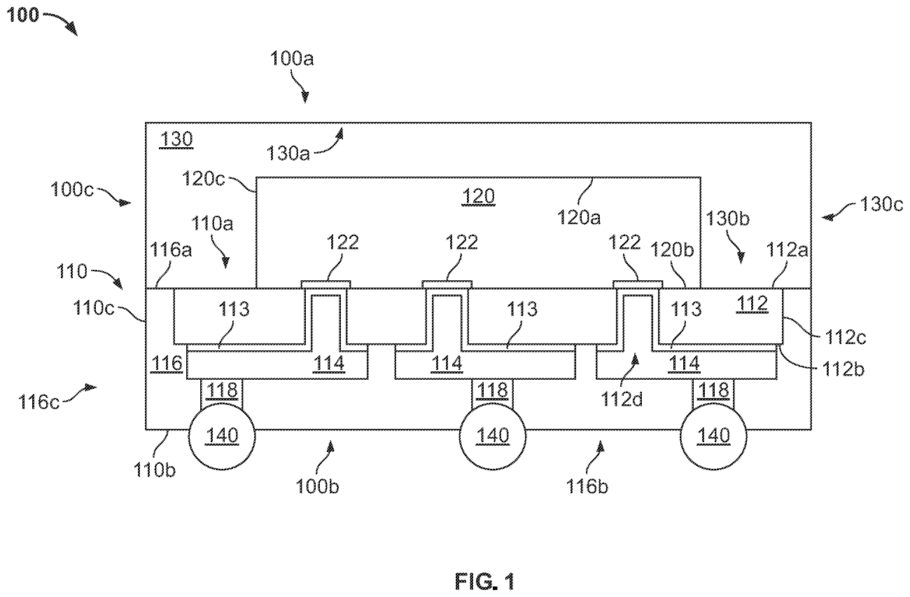

FIG. 1 depicts an example electronic device 100. As shown, the electronic device 100 may have a device top side 100a, a device bottom side 100b opposite the device top side 100a, and a device lateral side 100c between the device top side 100a and the device bottom side 100b. Further, the electronic device 100 may include a substrate 110, a semiconductor component 120, a component encapsulant 130, and external interconnect second structures 140 that protrude from and/or are positioned along the device bottom side 100b.

The substrate 110 may include a substrate top side 110a, a substrate bottom side 110b opposite the substrate top side 110a, and a substrate lateral side 110c between the substrate top side 110a and the substrate bottom side 110b. In general, the substrate 110 may provide a signal distribution structure that defines electrical paths between the substrate top side 110a and the substrate bottom side 110b.

To this end, the substrate 110 may include a first dielectric layer 112, a seed layer 113, a conductive pattern 114, a substrate encapsulant 116, and external interconnect first structures 118. The first dielectric layer 112 may have a first dielectric layer top side 112a, a first dielectric layer bottom side 112b opposite the first dielectric layer top side 112a, and a first dielectric layer lateral side 112c between the first dielectric layer top side 112a and the first dielectric layer bottom side 112b. The first dielectric layer 112 may further include first dielectric layer apertures 112d that pass through the first dielectric layer 112 between the first dielectric layer top side 112a and the first dielectric layer bottom side 112b.

The seed layer 113 of the substrate 110 may cover the first dielectric layer bottom side 112b. Moreover, the seed layer 113 may extend into the first dielectric layer apertures 112d. In various implementations, the seed layer 113 conforms to or lines inner walls of the first dielectric layer apertures 112d. Further, in various implementations, the seed layer 113 may extend through the first dielectric layer apertures 112d to define upper portions that contact interconnection structures 122 of the semiconductor component 120. Such upper portions of the seed layer 113 may be coplanar with the first dielectric layer top side 112a as shown. In various implementations, the upper portions may protrude above the first dielectric layer top side 112a or remain recessed below the first dielectric layer top side 112a.

The seed layer 113 may comprise any of a variety of materials. For example, the seed layer 113 may comprise copper. Also for example, the seed layer 113 may comprise one or more layers of any of a variety of metals such as silver, gold, aluminum, tungsten, titanium, nickel, molybdenum, etc. The seed layer 113 may be formed utilizing any of a variety of techniques such as sputtering, physical vapor deposition (PVD) processes, chemical vapor deposition (CVD) processes, electroless plating, electrolytic plating, etc.

The conductive pattern or layer 114 of the substrate 110 may comprise conductive traces that cover a bottom side of the seed layer 113. Moreover, the conductive pattern 114 may extend into the first dielectric layer apertures 112d and fill the seed layer lined inner walls of the first dielectric layer apertures 112d. The conductive pattern 114 may comprise any of a variety of materials such as copper, aluminum, nickel, iron, silver, gold, titanium, chromium, tungsten, palladium, combinations thereof, alloys thereof, equivalents thereof, etc.

Similar to the seed layer 113, the conductive pattern 114 may be formed utilizing any of a variety of techniques such as sputtering, physical vapor deposition (PVD) processes, chemical vapor deposition (CVD) processes, electroless plating, electrolytic plating, etc. However, in various implementations, the conductive pattern 114 may be grown or plated on the seed layer 113 via an electrolytic plating process, in which electrical current passes through the seed layer 113.

The substrate encapsulant 116 may surround and contact the first dielectric layer bottom side 112b, the first dielectric layer lateral side 112c, a lateral side of the seed layer 113, a bottom side of the conductive pattern 114, a lateral side of the conductive pattern 114, and lateral sides of the external interconnect first structures 118. As shown, the substrate encapsulant 116 may also surround and contact lateral sides of each external interconnect second structure 140. However, in various implementations, the external interconnect first structures 118 may protrude below the substrate encapsulant 116. In various other implementations, bottom sides of the external interconnect first structures 118 may be coplanar with the substrate bottom side 116b. In such implementations, the substrate encapsulant 116 may not surround or contact lateral sides of the external interconnect second structures 140.

As shown, the substrate encapsulant 116 may have a substrate encapsulant top side 116a, a substrate encapsulant bottom side 116b, and a substrate encapsulant lateral side 116c. In various implementations, the substrate encapsulant top side 116a and the first dielectric layer top side 112a are coplanar and may generally define the substrate top side 110a. Further, the substrate encapsulant bottom side 116b and the substrate encapsulant lateral side 116c may generally define the substrate bottom side 110b and the substrate lateral side 110c, respectively. Thus, as shown, a width of the substrate encapsulant 116 between opposite lateral sides 116c may be greater than a width of the first dielectric layer 112 between its corresponding lateral sides 112c.

The substrate encapsulant 116 may comprise any of a variety of characteristics. For example, the substrate encapsulant 116 may comprise any of a variety of encapsulating or molding materials such as resin, polymer, polymer composite material, polymer with filler, epoxy resin, epoxy resin with filler, epoxy acrylate with filler, silicone resin, combinations thereof, equivalents thereof, etc. The substrate encapsulant 116 may be formed in any of a variety of manners such as compression molding, transfer molding, liquid encapsulant molding, vacuum laminating, paste printing, film assisted molding, film pressing, spin coating, spraying, etc.

The external interconnect first structures 118 may be coupled to the conductive pattern 114. In particular, a top side of each external interconnect first structures 118 may be coupled to a bottom side of the conductive pattern 114. Moreover, a bottom side of each external interconnect first structures 118 may be exposed at the substrate encapsulant bottom side 116b. In various embodiments, the bottom side of the external interconnect first structures 118 may protrude below the substrate encapsulant bottom side 116b or may be coplanar with the substrate encapsulant bottom side 116b. However, as shown, the external interconnect first structures 118 may be recessed in the substrate encapsulant bottom side 116b in various implementations.

Each external interconnect first structure 118 may comprise any of a variety of materials such as copper, aluminum, nickel, iron, silver, gold, titanium, chromium, tungsten, palladium, combinations thereof, alloys thereof, equivalents thereof, etc. In various implementations, each external interconnect first structure 118 may comprise one or more electroplated conductive layers formed with the aid of the electroplating seed layer 113. Such electroplated conductive layers may form a variety of structures. For example, the external interconnect first structures 118 may be implemented as conductive pillars, conductive studs, conductive pins, conductive vias, under bump metal, etc. Thus, in various implementations, the seed layer 113 may be used by electrolytic plating processes to not only form layer(s) of the conductive pattern 114 but also layer(s) of each external interconnect first structure 118. Further, in various implementations, the external interconnect first structures 118 may comprise various non-electroplated conductive structures such as conductive pillars, conductive studs, conductive pins, conductive vias, under bump metal, conductive bumps, solder balls, solid core solder balls, and/or other conductive structures suitable for electrically coupling the semiconductor component 120 to external devices.

The semiconductor component 120 may have a component top side 120a, a component bottom side 120b opposite the component top side 120a, and a component lateral side 120c between the component top side 120a and the component bottom side 120b. The semiconductor component 120 may further include interconnection structures 122 such as contacts, dies pads, terminals, bumps, pillars, balls, etc. along the component bottom side 120b. In various implementations, the interconnection structures 122 may protrude from the component bottom side 120b such that bottom sides of the interconnections structures 122 are below the component bottom side 120b. However, in other implementations, the bottom sides of the interconnections structures 122 may be coplanar with the component bottom side 120b as shown in FIG. 1 or may be recessed such that the bottom sides of the interconnections structures 122 are above the component bottom side 120b.

In various implementations, the semiconductor components 120 may include one or more electrical components such as semiconductor dies with integrated circuits, packaged semiconductor dies, active components, passive components, etc. As such, the interconnection structures 122 may be coupled to such electrical components and provide electrical connections to such electrical components that permit external devices to interact (e.g., send and/or receive signals) with electrical components via the interconnection structure 122.

As shown, the interconnection structure 122 of the semiconductor component 120 may be electrically and physically coupled to the substrate top side 110a. In particular, the interconnection structures 122 may be electrically coupled to the conductive pattern 114 via the seed layer 113, and to the external interconnect first structure 118 via the conductive pattern 114. As shown, external interconnect second structures 140 may be coupled to the external interconnect first structures 118. As such, the substrate 110 may electrically couple one or more of the external interconnect second structures 140 to the semiconductor component 120.

The external interconnect second structures 140 may comprise and/or be referred to as solder balls, solder coated metal core balls (e.g., solder coated copper core balls), pillars, bumps, and/or copper pillars with solder caps, and/or copper bumps with solder caps. The external interconnect second structures 140 may comprise tin (Sn), silver (Ag), lead (Pb), copper (Cu), Sn—Pb, Sn37-Pb, Sn95-Pb, Sn—Pb—Ag, Sn—Cu, Sn—Ag, Sn—Au, Sn—Bi, Sn—Ag—Cu and/or Sn—Ag—Cu—Bi. In some examples, the external interconnect second structures 140 may be provided through a reflow process after forming a solder-containing conductive material on the bottom side of the external interconnect first structures 118 by a ball drop process. The external interconnect second structures 140 may couple the semiconductor component 120 to an external device. In particular, the external interconnect second structures 140 may permit external components to send and/or receive signals with the semiconductor component 120 via the substrate 110.

As shown, a width of the first dielectric layer 112 between its lateral sides 112c may be greater than a width of the semiconductor component 120 between its corresponding later sides 120c. As such, one or more conductive traces of the conductive pattern 114 and/or one or more of the external interconnect first structures 118 may extend laterally outside the footprint of the semiconductor component 120. As such, the substrate 110 may provide a signal distribution structure with a fan-out configuration. Namely, the external interconnect second structures 140 of the electronic device 100 have a greater footprint than the interconnection structures 122 of the semiconductor component 120.

The component encapsulant 130 may have a component encapsulant top side 130a, a component encapsulant bottom side 130b, and a component encapsulant lateral side 130c. As shown, the component encapsulant 130 may surround and contact the semiconductor component 120 and the substrate top side 110a. In particular, the component encapsulant 130 may surround and contact the component top side 120a and the component lateral side 120c. However, in various implementations, the component encapsulant may further underfill the semiconductor component 120 and contact the component bottom side 120b and/or the interconnection structure 122. Moreover, in some implementations, the component top side 120a may be exposed at the electronic device top side 100a. In such implementations, the components top side 120a and component encapsulant top side 130a may be coplanar and may generally define the electronic device top side 100a.

The component encapsulant 130 may comprise any of a variety of characteristics. For example, the component encapsulant 130 may comprise any of a variety of encapsulating or molding materials such as resin, polymer, polymer composite material, polymer with filler, epoxy resin, epoxy resin with filler, epoxy acrylate with filler, silicone resin, combinations thereof, equivalents thereof, etc. The component encapsulant 130 may be formed in any of a variety of manners such as compression molding, transfer molding, liquid encapsulant molding, vacuum laminating, paste printing, film assisted molding, film pressing, spin coating, spraying, etc.

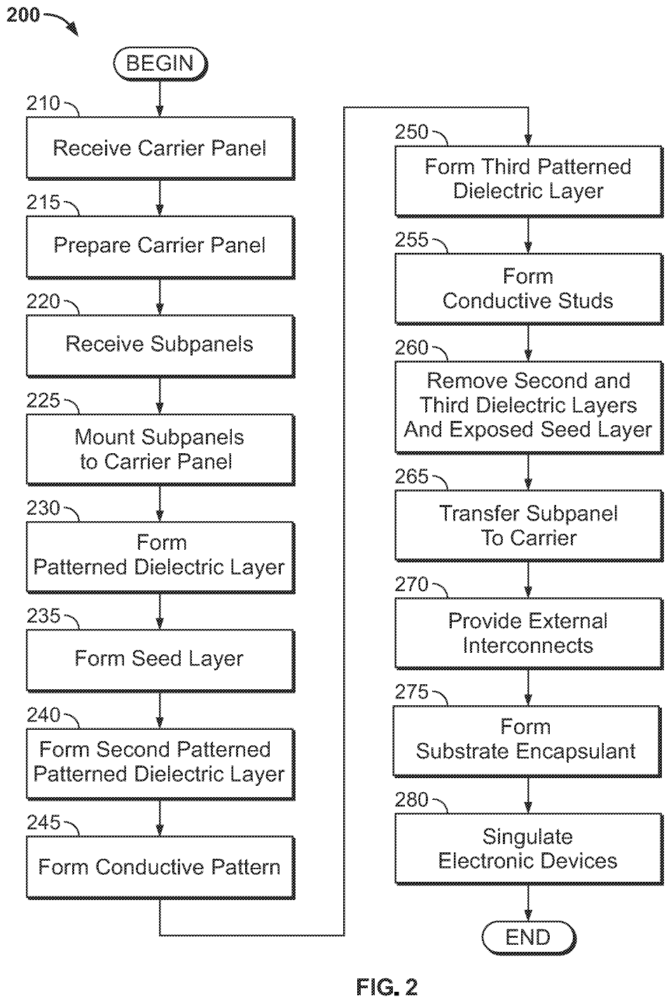

FIG. 2 shows a flow diagram of an example method 200 used by a manufacturing system to make the electronic device 100. A manufacturing system may vary the order of operations depicted in FIG. 2 without departing from the scope of this disclosure. Moreover, a manufacturing system may eliminate one or more of the depicted operations and/or add one or more operations without departing from the scope of this disclosure.

A manufacturing system may initiate the method 200 in response to any of a variety of causes or conditions, non-limiting examples of which are provided herein. For example, the manufacturing system may automatically initiate the method 200 in response to one or more signals received from one or more upstream or downstream manufacturing stations, in response to a signal from a central manufacturing line controller, upon arrival of components or manufacturing materials utilized during performance of the method 200, etc. Also, for example, the manufacturing system may initiate the method 200 in response to an operator command invoked by a user that requests a manufacturing station or other component of the manufacturing system to initiate the method 200.

At 210, the manufacturing system may receive a carrier panel, which may also be referred to herein as a panel or frame. The carrier panel may, for example, comprise a carrier panel to which a plurality of subpanels are to be mounted to form a hybrid panel.

The carrier panel may comprise a plurality of characteristics. For example, a carrier panel may have any of a variety of shapes. The carrier panel may, for example, be rectangular. The carrier panel may also, for example, be square, n-polygonal where n is an integer greater than 2, elliptical, circular, etc. The carrier top surface or bottom surface may be entirely planar, or the carrier top or bottom surface may have recesses or apertures (e.g., for the accommodation of subpanels).

The carrier panel may, for example, comprise any of a variety of materials. For example, the carrier panel may comprise metal (e.g., stainless steel, etc.). Also for example, the carrier panel may comprise glass (e.g., transparent glass, etc.). Additionally for example, the carrier panel may comprise ceramic. Further for example, the carrier panel may comprise semiconductor material (e.g., silicon, gallium arsenide, etc.). In an example implementation, the carrier panel may be formed of a material having a coefficient of thermal expansion (CTE) that is the same as or substantially the same as (e.g., within 5%, within 10%, within 25%, etc.) the CTE of subpanels that are to be mounted to the carrier panel (e.g., at 240). In another example implementation, the carrier panel may be formed of a material having a CTE that is within 50% of the CTE of the subpanels that are to be mounted to the carrier panel.

The carrier panel may provide structural support throughout processing of the subpanels mounted or coupled thereto or processing of the carrier panel. For example, the carrier panel may be formed to withstand temperatures experienced during such processing. In various implementations, during the forming of various signal redistribution structures, the manufacturing system may subject the carrier panel to temperatures reaching or exceeding 230 degrees Celsius for two or three or more hours. As such, the carrier panel may be design to withstand such temperatures without compromising its basic function of providing support and stability during manufacturing. Also, the carrier panel may be designed to withstand chemical exposures experienced during such processing. In various implementations, during the forming of various signal redistribution structures or other processes, the manufacturing system may subject the carrier panel to various chemicals such as propylene glycol methyl ether acetate (PGMEA), tetramethylammonium hydroxide (TMAH), cyclopentanone, sulfuric acid, hydrofluoric acid (0.5%), etc. The carrier panel may therefore be designed to withstand such chemicals without compromising its basic function of providing support and stability during manufacturing.

The manufacturing system at 215 may prepare the received carrier panel for subsequent processing. For example, the manufacturing system may prepare the received carrier panel for the mounting of subpanels thereto, for manufacturing processes to which the carrier panel may be exposed, etc. To this end, the manufacturing system at 215 may clean the received carrier panel. The manufacturing system may further inspect the received carrier panel to verify that the carrier panel meets manufacturing tolerances such as size, flatness, planarity, thickness, coefficient of thermal expansion (CTE) requirements, aperture requirements, transparency requirements, etc. Additionally, the manufacturing system at 215 may comprise verifying that the carrier panel has not been damaged during shipping or during previous manufacturing operations such as when carrier panels are reused.

The manufacturing system at 220 may receive subpanels for mounting to the carrier panel. The term subpanel, as utilized herein, may refer to any of a variety of types of subpanels. For example, a subpanel may have any of a variety of shapes such as circular, rectangular, rectangular strip, square, n-polygonal with n being an integer greater than 2, elliptical, etc. A subpanel may comprise any of variety of forms. For example, a subpanel may comprise a semiconductor wafer such as a wafer of integrated circuits output from a wafer fab process; an interposer wafer with or without active or passive components integrated therein; a reconstituted wafer comprising a plurality of semiconductor components and/or a plurality of semiconductor dies that have been previously singulated that are now coupled to each other with a joining material such as an molding material, epoxy resign, encapsulant, etc. Additionally, a subpanel may comprise an interposer or a substrate such as a cored substrate or a coreless substrate. Such an interposer or substrate be bare or may comprise electronic components such as semiconductor components, active components, passive components, etc. attached thereto.

The manufacturing system at 220 may receive a semiconductor wafer from a wafer fabrication facility, from an upstream process, etc. The wafer may be circular having a diameter of 2″, 4″, 8″, 12″, 300 mm, etc. The wafer may comprise any of a variety of semiconductor materials such as Silicon (Si), Gallium Arsenide (GaAs), InP, etc. The wafer may comprise microelectromechanical machine system (MEMS) components.

In some example implementations, the manufacturing system at 220 may comprise receiving subpanels in the form of reconstituted subpanels. Such reconstituted subpanels may comprise circular wafers, rectangular subpanels, square subpanels, etc. Such a reconstituted subpanel may comprise any of a variety of dimensions. For example, the reconstituted subpanel may have a circular diameter or side length of 2″, 4″, 8″, 12″, 300 mm, etc. Moreover, the reconstituted subpanel may comprise any of a variety of thicknesses. For example, a subpanel may be less than 100 μm thick in order to provide a relatively thin and flexible subpanel or may be greater than 300 μm to provide a relatively thick and inflexible subpanel.

The manufacturing system at 225 may mount subpanels received at 220 to the carrier panel received at 210 and prepared at 215. The manufacturing system at 225 may mount the subpanels to the carrier panel in any of a variety of manners, various non-limiting examples of which are provided herein. In various example implementation, the manufacturing system at 225 may mechanically clamp the subpanels to the carrier panel. For example, such mechanically clamping may comprise utilizing clips, magnets such as permanent magnets, etc. The manufacturing system at 225 may vacuum clamp the subpanels to the carrier panel.

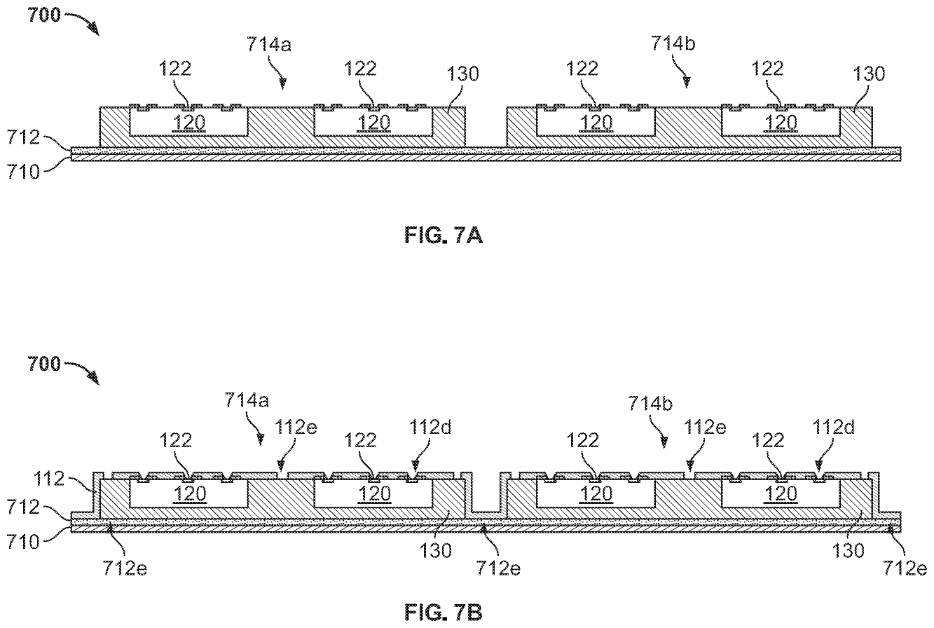

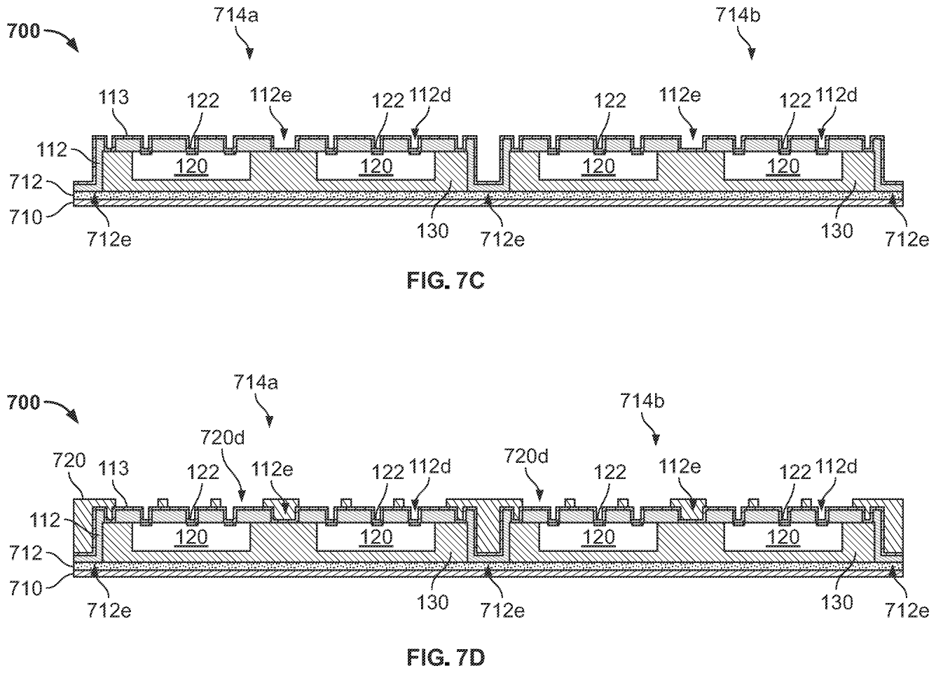

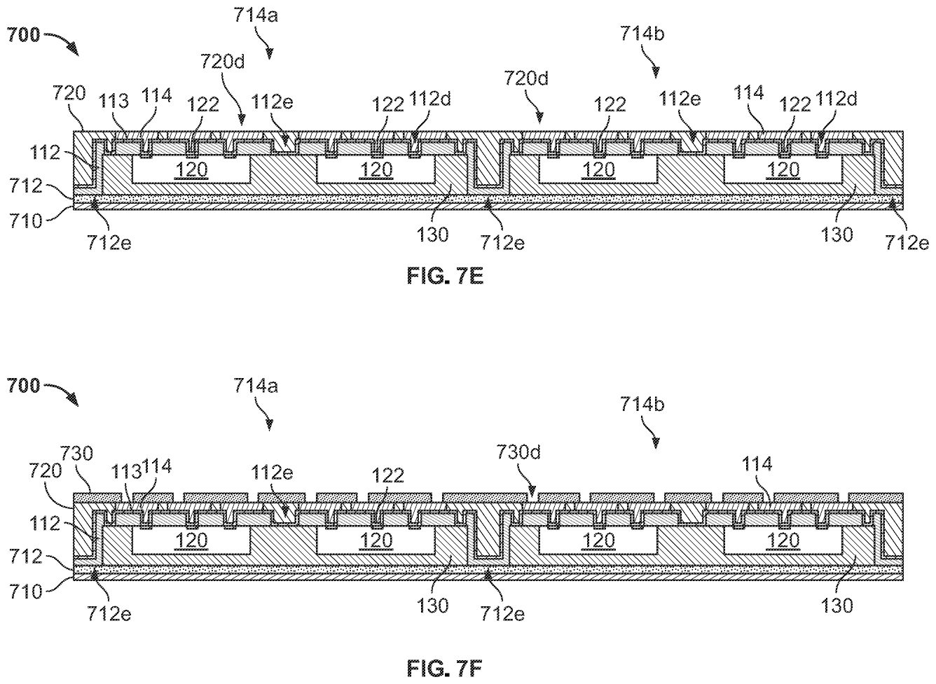

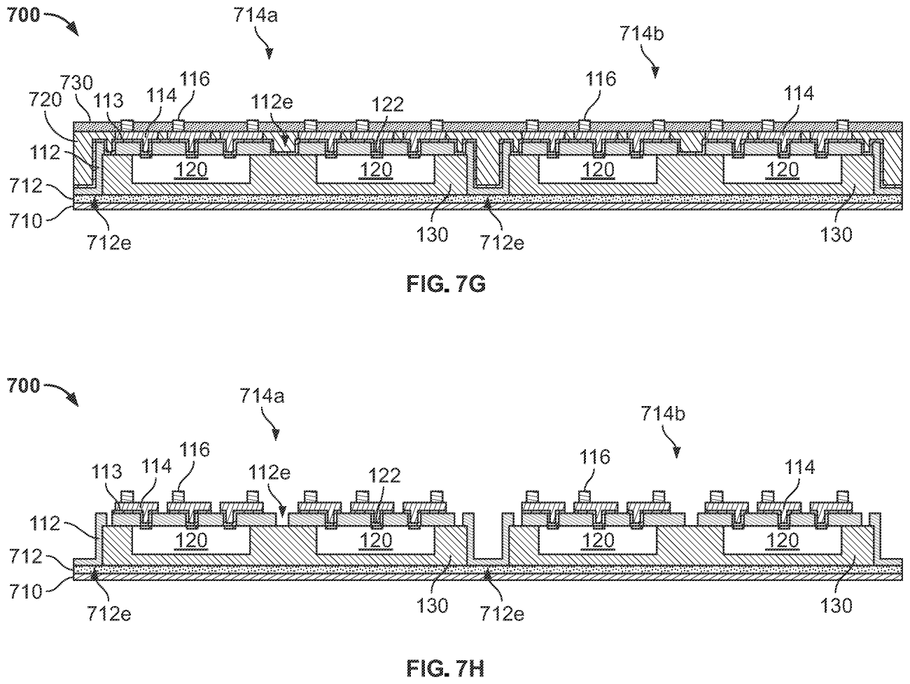

For example, as shown at FIG. 7A, the manufacturing system at 225 may form a panel 700 by mounting a first subpanel 714a and a second subpanel 714b to a carrier panel 710. The first subpanel 714a and the second subpanel 714b may be mounted to the carrier panel 710 via an adhesive material 712. The first subpanel 714a may comprise semiconductor components 120 (e.g., a semiconductor die, a packaged semiconductor die, etc.) and component encapsulant 130. Similarly, the second subpanel 714b may comprise semiconductor components 120 surrounded by component encapsulant 130.

As further shown, each semiconductor component 120 may include interconnection structures 122 such as contacts, dies pads, terminals, bumps, pillars, balls, etc. that are exposed at its front side. In some implementations, the interconnection structures 122 may protrude from the front side. In such implementations, the component encapsulant 130 may also extend over the front side of the semiconductor component 120 and/or may contact lateral sides of such protruding interconnection structures 122.

At 230, the manufacturing system may provide a patterned first dielectric layer 112 over the subpanels and carrier panel. For example, as shown in FIG. 7B, the manufacturing system may provide and pattern a first dielectric layer 112 over a top side of the panel 700. In particular, providing of the first dielectric layer 112 may include covering the front side of the semiconductor components 120 and a front side of the component encapsulant 130 for both subpanels 714a, 714b and any exposed portions 712e of the adhesive material 712. Moreover, patterning of the first dielectric layer 112 may include forming apertures 112d and singulation apertures 112e that pass between a first side 112a and a second side 112b of the first dielectric layer 112. The apertures 112d, 112e may expose underlying structures such as front sides of the semiconductor components 120 and/or interconnection structures 122 of the semiconductor components 120.

The manufacturing system at 235 may form a seed layer over the patterned first dielectric layer 112. For example, as shown in FIG. 7C, the manufacturing system may form an electroplating seed layer 113 over the panel 700. In particular, the manufacturing system may form the electroplating seed layer 113 by depositing or otherwise forming the seed layer 113 on the patterned first dielectric layer 112 such that the seed layer 113 covers the top sides of the subpanels 714a, 714b, the lateral sides of the subpanels 714a, 714b, the top side of the carrier panel 710 between adjacent subpanels 714a, 714b, etc. The seed layer 113 may comprise any of a variety of materials. For example, the seed layer 113 may comprise copper. Also for example, the seed layer 113 may comprise one or more layers of any of a variety of metals such as silver, gold, aluminum, tungsten, titanium, nickel, molybdenum, etc. The seed layer 113 may be formed utilizing any of a variety of techniques such as sputtering, physical vapor deposition (PVD) processes, chemical vapor deposition (CVD) processes, electroless plating, electrolytic plating, etc. As addressed further below, the manufacturing system may use the seed layer 113 during one or more subsequent electroplating processes.

At 240, the manufacturing system may provide a patterned second dielectric layer 720 over the seed layer 113. For example, as shown in FIG. 7D, the manufacturing system may provide the patterned second dielectric layer 720 over a top side of the seed layer 113. In particular, providing of the second dielectric layer 720 may include covering the top side of the seed layer 113 including portions of the seed layer 113 over the interconnection structures 122 of the semiconductor components and portions of the seed layer 113 over portions 712e of the adhesive material 712. Moreover, patterning of second dielectric layer 720 may include forming apertures 720d that pass through the second dielectric layer 720. The apertures 720d may expose underlying structures such as portions of the seed layer 113 over the interconnection structures 122 of the semiconductor components 120 and may define conductive traces or paths of a subsequently formed conductive pattern.

The manufacturing system at 245 may form a conductive pattern 114 comprising conductive traces defined by the patterned second dielectric layer 720. As shown in FIG. 7E, the manufacturing system may form a conductive pattern 114 over the seed layer 113. The manufacturing system may electroplate the conductive pattern 114 on portions of the seed layer 113 exposed by apertures 720d through the patterned second dielectric layer 720. To this end, the manufacturing system may apply an electric current to the seed layer 113 and electroplate the conductive pattern 114 on the seed layer 113. In some implementations, the manufacturing system may planarize the top sides of the conductive pattern 114 and the patterned second dielectric layer 720 before proceeding to 250. In various implementations, the conductive pattern 114 is formed to be thicker than a typical redistribution layer thickness (RDL). For example, the conductive pattern 114 in various implementations can have a target thickness of 20-30 μm, whereas a typical RDL thickness is in the range of 2-10 μm. The thicker target thickness of the conductive pattern 114 may provide improved electrical characteristics and/or thermal dissipation, especially with regard to high frequency signals.

At 250, the manufacturing system may provide a patterned third dielectric layer 730 over the conductive pattern 114. As shown in FIG. 7F, the manufacturing system may form a patterned third dielectric layer 730 over the conductive pattern 114 and exposed portions of the patterned second dielectric layer 720. Providing of the third dielectric layer 730 may include covering the top side of the conductive pattern 114 and the top side of the patterned second dielectric layer 720. Moreover, patterning of third dielectric layer 730 may include forming apertures 730d that pass through the third dielectric layer 730. The apertures 730d may expose underlying structures such as portions of the conductive pattern 114 and may define sidewalls of a subsequently formed external interconnect first structures.

The manufacturing system at 255 may form external interconnect first structures 118 on exposed portions of the conductive pattern 114. As shown in FIG. 7G, the manufacturing system may form external interconnect first structures 118 on the conductive pattern 114. In particular, the manufacturing system may form the external interconnect first structures 118 such that each external interconnect first structure 118 extends through an aperture 730d of the patterned third dielectric layer 730 and contacts an exposed portion of the conductive pattern 114. In some implementations, the manufacturing system may apply an electric current to the seed layer 113 in order to form one or more electroplated layers of the external interconnect first structures 118. In this manner, the manufacturing system may reuse the seed layer 113 to form not only layer(s) of the conductive pattern 114 but also layer(s) of the external interconnect first structures 118. In various implementations, the external interconnect first structures 118 may comprise any of a variety of materials such as copper, aluminum, nickel, iron, silver, gold, titanium, chromium, tungsten, palladium, combinations thereof, alloys thereof, equivalents thereof, etc., but the scope of the present disclosure is not necessarily limited thereto. Moreover, in various implementations, the external interconnect first structures 118 may have a target thickness of 20-30 μm. In contrast, under bump metal (UBM) typically has a thickness of 5-10 μm. The greater thickness provided by the external interconnect first structure 118 may aid in physically separating the semiconductor component 120 from a printed circuit board (PCB) or other component to which the electronic device 100 is coupled via the external interconnect second structures 140. As such, the external interconnect first structures 117 may provide a superior decoupling of the semiconductor component 120 from an external PCB in comparison to a UBM of typical thickness.

Per the method 200, the manufacturing system may form a substrate 110 having only a single conductive pattern 114. However, in other implementations, alternating layers of patterned dielectric layers and conductive patterns may be repeated so as to form a substrate having multiple layers of conductive patterns and their associated conductive traces. Moreover, the manufacturing system may form such additional conductive patterns by applying an electric current to seed layer 113 and electroplating such conductive patterns. Thus, the same seed layer 113 may be reused to form multiple layers of conductive patterns and/or external interconnect first structures.

Further, the manufacturing system per the method 200 provides three patterned dielectric layers 112, 720, 730. The manufacturing system may provide the three patterned dielectric layers 112, 720, 730 via example processes described below. In at least one implementation, the first dielectric layer 112 is provided by a photo-definable dry film or photo-definable ABF build-up film and the dielectric layers 720, 730 are provided by laminated photoresist. However, each dielectric layer 112, 720, 730 may be independently provided by any of the below processes. Thus, each dielectric layer 112, 720, 730 may be provided by a different one of the following processes, each dielectric layer 112, 720, 730 may be provided by a same one of the following processes, etc.

In some implementations, one or more of the dielectric layers 112, 720, 730 may be provided per a conventional photolithography processes. Such a photolithography process may provide a dielectric layer over lower layers of the substrate, form a patterned photoresist layer over the dielectric layer using a mask and radiation, transfer the pattern of the photoresist layer to the dielectric layer via etching or another process, and remove the patterned photoresist layer. The one or more of the dielectric layers 112, 720, 730 may comprise one or more layers of any of a variety of dielectric materials. For example, the dielectric layers 112, 720, 730 may include inorganic dielectric materials (e.g., Si₃N₄, SiO₂, SiON, SiN, oxides, nitrides, combinations thereof, equivalents thereof, etc.) or organic dielectric material (e.g., a polymer, polyimide (PI), benzocyclobutene (BCB), polybenzoxazole (PBO), bismaleimide triazine (BT), a molding material, a phenolic resin, an epoxy, silicone, acrylate polymer, combinations thereof, equivalents thereof, etc.). In such implementation, the dielectric layers 112, 720, 730 may be provided using any one or more of a variety of processes (e.g., spin coating, spray coating, printing, sintering, thermal oxidation, physical vapor deposition (PVD), chemical vapor deposition (CVD), atomic layer deposition (ALD), low pressure chemical vapor deposition (LPCVD), plasma enhanced chemical vapor deposition (PECVD), plasma vapor deposition (PVD), sheet lamination, evaporating, etc.).

In various embodiments, one or more of dielectric layers 112, 720, 730 may be provided by a dry film or ABF film (hereafter “dry film”) of dielectric material. In particular, dry films are laminated rather than spin-coated and may provide a dielectric layer (e.g., dielectric layer 112, 720, or 730) with a thickness having a target range of 20-30 μm. Conversely, liquid films formed, via one of the many above-noted processes (e.g., spin-coating), generally provide a dielectric layer (e.g., dielectric layer 122, 720, or 730) having thickness in the range of 3-10 μm. Thus, the dry films may provide a dielectric layer that is 2 to 10 times thicker than that provided by the above-note processes.

In various implementations, the dry film is photo-definable and thus may be patterned via photolithography processes such as stepper photolithography processes and mask-less laser-direct imaging (LDI) processes. LDI processes generally provide a lower exposure dose than stepper processes. For example, in various implementations, the exposure dose for LDI dry films is in the range of 50-100mJ/cm², whereas the exposure dose for stepper dry films is in the range of about 250-1000mJ/cm2.

Moreover, in certain implementations, the dry film comprises a low loss tangent dielectric material. Examples of such photo-definable and/or low loss tangent dielectric materials include photo imageable dielectric films (e.g., PVI-3 HR-200) from Taiyo Ink Mfg. Co., Ltd. Moreover, for purposes of the present disclosure, dielectric materials having a low loss tangent of 0.015 or less are considered low loss tangent dielectric materials. In various embodiments, the dielectric materials of the dry film have a loss tangent less than 0.015, less than 0.010, between 0.003 and 0.015, or between 0.003 and 0.010. Such a low tangent dielectric may improve signal integrity for high frequency applications.

The dry film may be laminated over exposed lower layers of the substrate 110, a mask or reticle may be placed over the dry film, and radiation (e.g., ultra-violet light) may pass through openings in the mask or directly from a laser source. In some implementations, exposure of the dry film to the radiation hardens such exposed portions of the dry film. In other implementations, exposure of the dry film to the radiation breaks down or softens such exposed portions of the dry film. Regardless of whether the exposed portions or non-exposed portions are the softer portions of the dry film, the softened or non-hardened parts of the dry film may be removed via solvents and a pattern may be transferred to the dry film layer to form one or more of the patterned dielectric layers 112, 720, 730. Thus, in various implementations, one or more of the dielectric layers 112, 720, 730 may be patterned without the aid of a separate photoresist layer between the mask and the dielectric layer 112, 720, 730 as is typical in conventional photolithography processes. As such, the manufacturing system of the present disclosure may eliminate steps of a conventional patterning process (e.g., patterning a photoresist layer and its subsequent removal) for forming one or more of the dielectric layers 112, 720, 730.

As noted above, one or more of the dielectric layers 112, 720, 730 may be implemented using photo-definable dry film. However, in some implementations, one or more of the dielectric layers 112, 720, 730 may be formed using a dry film that is not photo-definable. In such implementations, the manufacturing process may laminate the dry film over lower layers of the substrate and then pattern the dry film using laser ablation, in which a laser is used to directly pattern or cut through the dry film.

Finally, one or more of the dielectric layers 720, 730 may be implemented using a photoresist as the patterned dielectric layer itself. To this end, the manufacturing system may spin coat a photoresist layer over lower layers of the substrate and pattern the photoresist layer using a mask and exposing the photoresist to radiation through openings in the mask. In such implementations, the patterned photoresist layers itself is used as one or more of the patterned dielectric layers 720, 730 without transferring the pattern of the photoresist layer to the dielectric layer via etching or another process, and subsequently removing the patterned photoresist layer.

Returning to the flow of FIG. 2, the manufacturing system at 260 may remove the patterned dielectric layers 720, 730 and the exposed portions of the seed layer 113. For example, as shown in FIG. 7H, the manufacturing system may remove the dielectric layers 720, 730 and the portions of the seed layer 113 exposed after removal of the dielectric layer 720, 730. To this end, the manufacturing system may strip the dielectric layers 720, 730 from the subpanels 714a, 714b exposing portions of the seed layer 113. As shown, the removal of the dielectric layer 720 may expose the singulation apertures 112d and portions of the seed layer 113 in such singulation apertures 112d. The manufacturing system may then etch away the exposed portions of the seed layer 113 including seed layer portions in the singulation apertures 112d. As further shown, portions of the seed layer 113 between the patterned first dielectric layer 112 and the conductive pattern 114 may be retained.

The manufacturing system at 265 may transfer each subpanel to a respective carrier such that the manufacturing system may perform further operations at a subpanel level. First, the manufacturing system may remove each subpanel 714a, 714b from the carrier panel 710. The manufacturing system may perform such removal in any of a variety of manners, various non-limiting examples of which are provided herein. For example, the manufacturing system may remove the subpanels 714a, 714b by a heating and pulling process in which the manufacturing system applies heat and pulls subpanels 714a, 714b from the carrier panel 710 and/or adhesive material 712; by an illuminating and pulling process in which the manufacturing system illuminates the adhesive 712 through the carrier panel 710 to reduce its adhesive properties and pulls subpanels 714a, 714b from the carrier 410 and adhesive material 412; and/or by applying a shear force, etc.

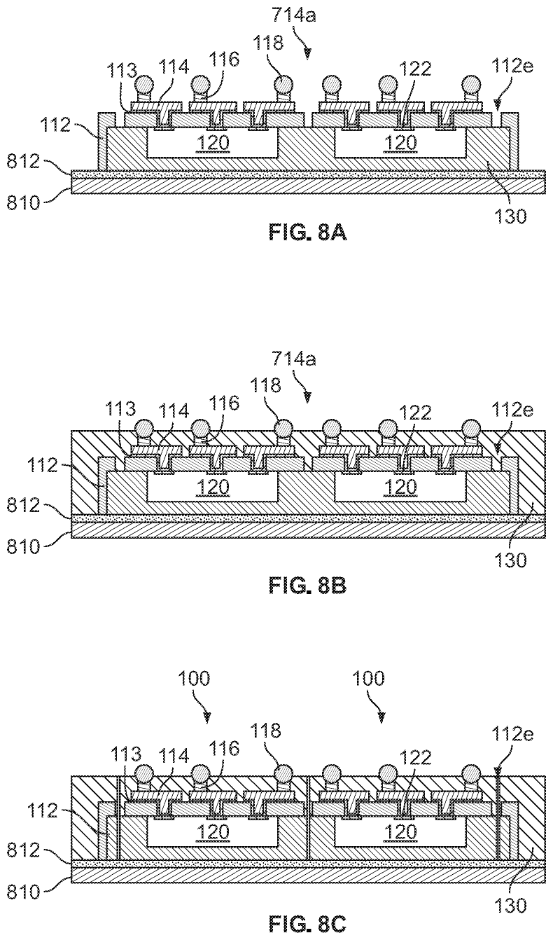

The manufacturing system may then attach each subpanel 714a, 714b to a respective carrier. For example, FIG. 8A depicts subpanel 714a attached to carrier subpanel 810 via an adhesive material 812. The carrier subpanel 810 and adhesive material 812 may share characteristics with any of the carriers and adhesive materials or the forming thereof discussed herein.

At 270, the manufacturing system may provide semiconductor components of the subpanel with external interconnect second structures. For example, as shown in FIG. 8A, the manufacturing system may provide each external interconnect first structure 118 with a corresponding external interconnect second structure 140. To this end, the manufacturing system may attach or form solder balls, solder coated metal core balls (e.g., solder coated copper core balls), pillars, bumps, and/or copper pillars with solder caps, and/or copper bumps with solder caps on the external interconnect first structures 118. In some implementations, the manufacturing system may provide the external interconnect second structures 140 through a reflow process after forming a solder-containing conductive material on the bottom side of each external interconnect first structures 118 by a ball drop process.

The manufacturing system at 275 may form a substrate encapsulant 116. For example, as shown in FIG. 8B, the manufacturing system may form the substrate encapsulant 116 over the conductive pattern 114 such that it surrounds and contacts the front sides and lateral sides of the conductive pattern 114 and the first dielectric layer 112. As further shown, the substrate encapsulant 116 fills the singulation apertures 112e and contacts a front side of the component encapsulant 130. The substrate encapsulant 116 may comprise any of a variety of characteristics. For example, the substrate encapsulant 116 may comprise any of a variety of encapsulating or molding materials such as resin, polymer, polymer composite material, polymer with filler, epoxy resin, epoxy resin with filler, epoxy acrylate with filler, silicone resin, combinations thereof, equivalents thereof, etc. The manufacturing system may form substrate encapsulant 116 in any of a variety of manners such as compression molding, transfer molding, liquid encapsulant molding, vacuum laminating, paste printing, film assisted molding, film pressing, spin coating, spraying, etc. In various implementations, the manufacturing system may form the substrate encapsulant 116 using a film assisted molding that encapsulates lateral sides or portions thereof of the external interconnect second structures 140.

At 280, the manufacturing system may singulate the subpanels into electronic devices. As shown in FIG. 8C, the manufacturing system may physically saw through the substrate encapsulant 116 and the component encapsulant 130 in order to singulate an electronic device 100 of the subpanel 714a from other electronic device(s) 100 of the subpanel 714a. Such sawing or singulation may pass through singulation apertures 112e of the first dielectric layer 112. As such, the first dielectric layer 112 may be spared from some of the physical forces associated with the singulation process. Furthermore, the first dielectric layer lateral sides 112c may remain encapsulated in the substrate encapsulant 116, thus further protecting the first dielectric layer 112.

Per the above, the external interconnect second structures 140 are provided on the external interconnect first structures 118 in FIG. 8A before encapsulating with component encapsulant 130 in FIG. 8B. However, in some implementations, the substrate 110 and semiconductor components 120 may be encapsulated with the component encapsulant 130 prior to providing the external interconnect second structures 140. In such implementations, a portion of a top side of the component encapsulant 130 may be removed through etching, grinding, etc. to expose top surfaces of the external interconnect first structures 118. After exposing the external interconnect first structures 118, the external interconnect second structures 140 may be provided on the exposed surfaces of the external interconnect first structures 118.

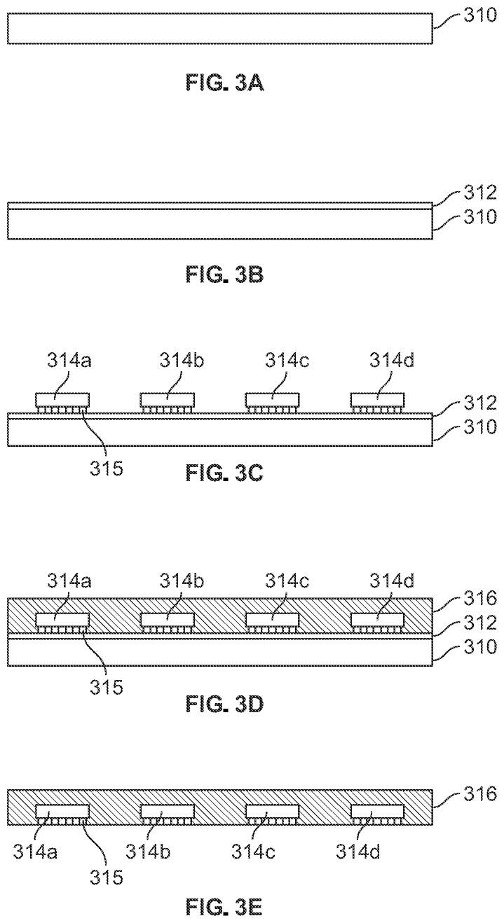

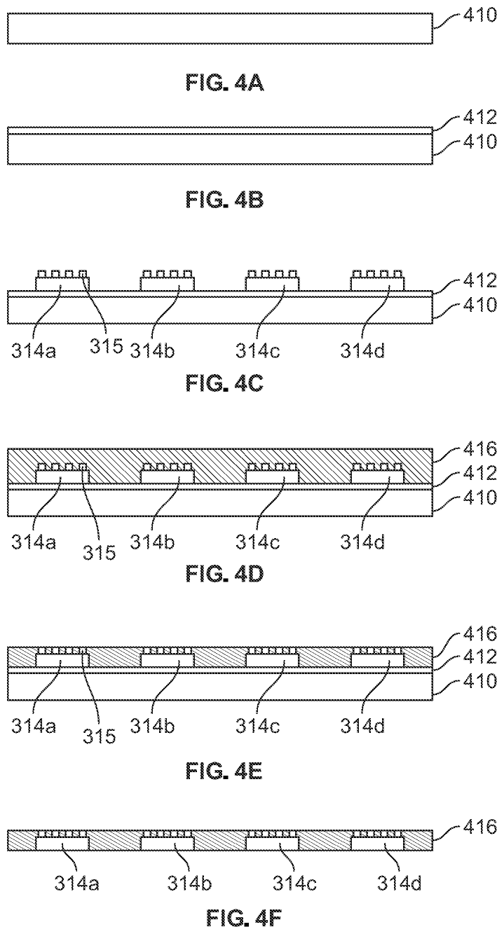

As explained above, the manufacturing system at 220 may receive subpanels comprising reconstituted wafers. In various implementations, instead of receiving such subpanels at 220, the manufacturing system may form subpanels of reconstituted wafers. To this end, FIGS. 3A-3E depict a face-down, a front-side-down, or active-side-down example method which the manufacturing system may use to form subpanels of reconstituted wafers. Similarly, FIGS. 4A-4F depict a face-up, a front-side-up, or a active-side-up example method which the manufacturing system may use to form subpanels of reconstituted wafers.

As shown at FIG. 3A, the manufacturing system may receive an example carrier 310 per the example method. The example carrier 310 may comprise any of a variety of characteristics. For example, the example carrier 310 may be circular, rectangular, shaped like the reconstituted subpanel to be formed thereon etc. Further, the example carrier 310 may be formed from a variety of materials such as glass, semiconductor material (e.g., silicon, etc.), metal (e.g., stainless steel, etc.), ceramic, etc.

As shown at FIG. 3B, the manufacturing system may prepare the carrier 310. Such preparing may be performed in any of a variety of manners, various non-limiting examples of which are provided herein. For example, the manufacturing system may clean the received carrier 310, prepare the carrier 310 for the application of various materials thereon, etc. In particular, the manufacturing system may form an adhesive material 312 (e.g., a layer of adhesive material) on a top side of the carrier 310. The adhesive material 312 may comprise any of a variety of characteristics, non-limiting examples of which are discussed herein. The adhesive material 312 may, for example, comprise a thermal-releasable adhesive, a light-releasable adhesive (e.g., UV-releasable, etc.), a die-attach film, etc. The manufacturing system may form the adhesive material 312 in any of a variety of manners, for example, printing; spraying; applying or laminating a preformed adhesive tape or film; spin-coating; vapor-depositing; etc. In general, the adhesive material 312 or the forming thereof may share characteristics with any of the adhesive materials or the forming thereof discussed herein.

The manufacturing system at FIG. 3C may include mounting semiconductor dies, electrical circuits, MEMS circuits, etc. to the carrier 310. Such mounting may be performed in any of a variety of manners, various non-limiting examples of which are provided herein. In particular, the manufacturing system may apply or adhere a plurality of semiconductor dies or semiconductor components 314a, 314b, 314c, and 314d to the carrier 310 via the adhesive material 312. The example semiconductor dies 314a-314d are shown mounted in a face-down configuration with the front sides of the semiconductor dies 314a-314d or interconnection structures at the front sides of the semiconductor dies 314a-314d facing the adhesive material 312 and the carrier 310. In some examples, the front sides of the semiconductor dies 314a-314d may comprise or be referred to as active sides or interconnect sides of the semiconductor dies 314a-314d. In various implementations, a pick-and-place machine of the manufacturing system may place or press the example semiconductor dies 314a-314d onto the adhesive material 312. In some implementations, interconnection structures 315 such as terminals, bond pads, pillars, posts, bumps, balls, etc. may protrude from front sides of the semiconductor dies 314a-314d such that a gap is defined between the front sides of the semiconductor dies 314a-314d and the adhesive material 312. In some examples, interconnection structures 315 may be substantially coplanar with the front sides of the semiconductor dies 314a-314d, or the front sides of semiconductor dies 314a-314d may contact the adhesive material 312. In some examples, the interconnection structures 315 may be recessed into the front sides of the semiconductor dies 314a-314d and may, but need not, contact the adhesive material 312.

At FIG. 3D, the manufacturing system may encapsulate the mounted semiconductor dies 314a-314d. Such encapsulating may be performed in any of a variety of manners, various non-limiting examples of which are provided herein. In particular, the manufacturing system may form an encapsulating material 316 around the semiconductor dies 314a-314d. As shown, the encapsulating material 316 may surround and contact all sides of the dies 314a-314d (e.g., top side, bottom side, and lateral sides), but the scope of this disclosure is not limited to such coverage. For example, the front sides of the semiconductor dies 314a-314d may be partially or entirely exposed from the encapsulating material 316. In an example implementation, a front side of the encapsulating material 316 and respective front sides of the semiconductor dies 314a-314d may be coplanar or substantially coplanar (e.g., within a 5% height deviation from a reference plane at the bottom of the reconstituted subpanel, within a 10% height deviation from a reference plane at the bottom of the reconstituted subpanel, etc.). Further, a portion of the encapsulating material 316 may be below the semiconductor dies 314a-314d such that the encapsulating material 316 laterally contacts and/or surrounds interconnection structures 315 of the semiconductor dies 314a-314d. However, not all implementations necessarily include such a configuration. For example, the bottom sides of the semiconductor dies 314a-314d may be free of the encapsulating material 316.

The encapsulant or encapsulating material 316 may comprise any of a variety of characteristics. For example, the encapsulating material 316 may comprise any of a variety of encapsulating or molding materials such as resin, polymer, polymer composite material, polymer with filler, epoxy resin, epoxy resin with filler, epoxy acrylate with filler, silicone resin, combinations thereof, equivalents thereof, etc. The manufacturing system may form the encapsulating material 316 in any of a variety of manners such as compression molding, transfer molding, liquid encapsulant molding, vacuum laminating, paste printing, film assisted molding, film pressing, spin coating, spraying, etc.

The manufacturing system at FIG. 3E may remove the carrier 310 and the adhesive material 312. The manufacturing system may perform such removal in any of a variety of manners, various non-limiting examples of which are provided herein. As shown, the carrier 310 and/or adhesive material 312 may be temporary structures which the manufacturing system may remove by performing a grinding and/or etching process; by a heating and pulling process in which heat is applied and the carrier 310 and/or adhesive material 312 are pulled from the encapsulating material 316 and the semiconductor dies 314a-314d; by an illuminating and pulling process in which the manufacturing system illuminates the adhesive material 312 through the carrier 310 to reduce its adhesive properties and pulls the carrier 310 and adhesive material 312 from the encapsulating material 316 and the semiconductor dies 314a-314d; and/or by the manufacturing system applying a shear force, etc. As shown in FIG. 3E, after the removal of the carrier 310 and adhesive material 312, interconnection structures 315 such as terminals, bond pads, pillars, posts, bumps, balls, etc. at the bottom sides of the semiconductor dies 314a-314d may be exposed at a bottom surface of the encapsulating material 316.

Referring now to FIGS. 4A-4F, the example method for forming a subpanel comprising reconstituted wafer is explained. Per such method, the manufacturing system at FIG. 4A may receive an example carrier 410. The manufacturing system may perform such receiving in any of a variety of manners, various non-limiting examples of which are provided herein. The example carrier 410 may comprise any of a variety of characteristics. For example, the example carrier 410 may be circular, rectangular, shaped like the reconstituted subpanel to be formed thereon, etc. The example carrier 410 may comprises a variety of materials such as glass, semiconductor material (e.g., silicon, etc.), metal (e.g., stainless steel, etc.), ceramic, etc.

At FIG. 4B, the manufacturing system may prepare the carrier 410. The manufacturing system may perform such preparing in any of a variety of manners, various non-limiting examples of which are provided herein. For example, the manufacturing system may clean the received carrier 410, prepare the carrier 410 for the application of various materials thereon, etc. In particular, as shown at FIG. 4B, the manufacturing system may apply an adhesive material 412 (e.g., a layer of adhesive material) on a top side of the carrier 410. The adhesive material 412 may comprise any of a variety of characteristics, non-limiting examples of which are discussed herein. The adhesive material 412 may, for example, comprise a thermal-releasable adhesive, a light-releasable adhesive (e.g., UV-releasable, etc.), a die-attach film, etc. The manufacturing system may form the adhesive material 412 in any of a variety of manners, for example, printing; spraying; applying or laminating a preformed adhesive tape or film; spin-coating; vapor-depositing; etc. The adhesive material 412 or the forming thereof may share characteristics with any of the adhesive materials or the forming thereof discussed herein.

The manufacturing system at FIG. 4C may comprise mounting semiconductor dies, semiconductor components, electrical circuits, MEMS circuits, etc. to the carrier 410. The manufacturing system may perform such mounting in any of a variety of manners, various non-limiting examples of which are provided herein. As shown at FIG. 4C, the manufacturing system may apply or adhere a plurality of semiconductor dies or semiconductor components 314a, 314b, 314c, and 314d to the carrier 410 via the adhesive material 412. In particular, the example semiconductor dies 314a-314d may be mounted in a face-up configuration with the front sides of the semiconductor dies 314a-314d or interconnection structures formed on the semiconductor dies 314a-314d facing upward or away from the adhesive material 412. A pick-and-place machine of the manufacturing system may place or press the example semiconductor dies 314a-314d onto the adhesive material 412. In some examples, interconnection structures 215 such as terminals, bond pads, pillars, posts, bumps, balls, etc. may protrude from the front sides of the semiconductor dies 314a-314d. In some examples, interconnection structures 215 may be substantially coplanar with the front sides of the semiconductor dies 314a-314d. In some examples, the interconnection structures 415 may be recessed into the front sides of the semiconductor dies 314a-314d.

The manufacturing system at FIG. 4D may encapsulate the mounted semiconductor dies or semiconductor components 314a-314d. The manufacturing system may perform such encapsulating in any of a variety of manners, various non-limiting examples of which are provided herein. As shown, the manufacturing system may form an encapsulating material 416 around the semiconductor dies 314a-314d. In particular, the encapsulating material 416 may surround and/or contact lateral and front sides of the semiconductor dies 314a-314d, but the scope of this disclosure is not necessarily limited to such coverage. For example, the front sides of the semiconductor dies 314a-314d may be entirely exposed from the encapsulating material 416. In example implementations, a portion of the encapsulating material 416 may be above the semiconductor dies 314a-314d and may laterally contact and/or surround interconnection structures 415 of the semiconductor dies 314a-314d. However, not all implementations necessarily include such a configuration. In example implementations, the encapsulating material 416, respective front sides of the semiconductor dies 314a-314d, and/or interconnection structures 415 thereon may be coplanar or substantially coplanar (e.g., within a 5% height deviation from a reference plane at the bottom of the reconstituted subpanel, within a 10% height deviation from a reference plane at the bottom of the reconstituted subpanel, etc.).

The encapsulating material 416 may comprise any of a variety of characteristics. For example, the encapsulating material 416 may comprise any of a variety of encapsulating or molding materials such as resin, polymer, polymer composite material, polymer with filler, epoxy resin, epoxy resin with filler, epoxy acrylate with filler, silicone resin, combinations thereof, equivalents thereof, etc. The manufacturing system may form the encapsulating material 416 in any of a variety of manners such as compression molding, transfer molding, liquid encapsulant molding, vacuum laminating, paste printing, film assisted molding, film pressing, spin coating, spraying, etc.

As shown at FIG. 4E, in various implementations, the manufacturing system may cover the front sides of the semiconductor dies 314a-314d and/or interconnection structures 415 with the encapsulating material 416. For such implementations, the manufacturing system may thin or planarize the encapsulating material 416 and/or interconnection structures 415 via grinding, etching, etc. to thin and expose the front sides of the semiconductor dies 314a-314d or the top sides of interconnection structures 415. In an example implementation, a top side of the encapsulating material 416 and respective front sides of the semiconductor dies 314a-314d or interconnection structures 415 may be coplanar or substantially coplanar (e.g., within a 5% height deviation from a reference plane at the bottom of the reconstituted panel, within a 10% height deviation from a reference plane at the bottom of the reconstituted panel, etc.).

Note that the method of FIGS. 3A-3E may further include a thinning or planarization process similar to FIG. 4E. Such thinning or planarizing may thin or planarize the encapsulating material 316 at FIG. 3D and/or the front sides of the semiconductor dies 314a-314d at FIG. 3E.

The manufacturing system at FIG. 4F may remove the carrier 410 and/or the adhesive material 412. The manufacturing system may perform such removal in any of a variety of manners, various non-limiting examples of which are provided herein. As shown, the carrier 410 and/or adhesive material 412 may be temporary structures which the manufacturing system may remove by performing a grinding and/or etching process; by a heating and pulling process in which the manufacturing system applies heat and pulls the carrier 410 and/or adhesive material 412 from the encapsulating material 416 and the semiconductor dies 314a-314d; by an illuminating and pulling process in which the manufacturing system illuminates the adhesive material 412 through the carrier 410 to reduce its adhesive properties and pulls the carrier 410 and adhesive material 412 from the encapsulating material 416 and the semiconductor dies 314a-314d; and/or by applying a shear force, etc.

As shown in FIG. 4F, after the removal of the carrier 410 and adhesive material 412, the back sides of the semiconductor dies 314a-314d may be exposed at a bottom surface of the encapsulating material 416. In an example implementation, a bottom side of the encapsulating material 416 and respective back sides of the semiconductor dies 314a-314d may be coplanar or substantially coplanar (e.g., within a 5% height deviation from a reference plane at a top surface of the encapsulating material, within a 10% height deviation from a reference plane at a top surface of the encapsulating material, etc.).

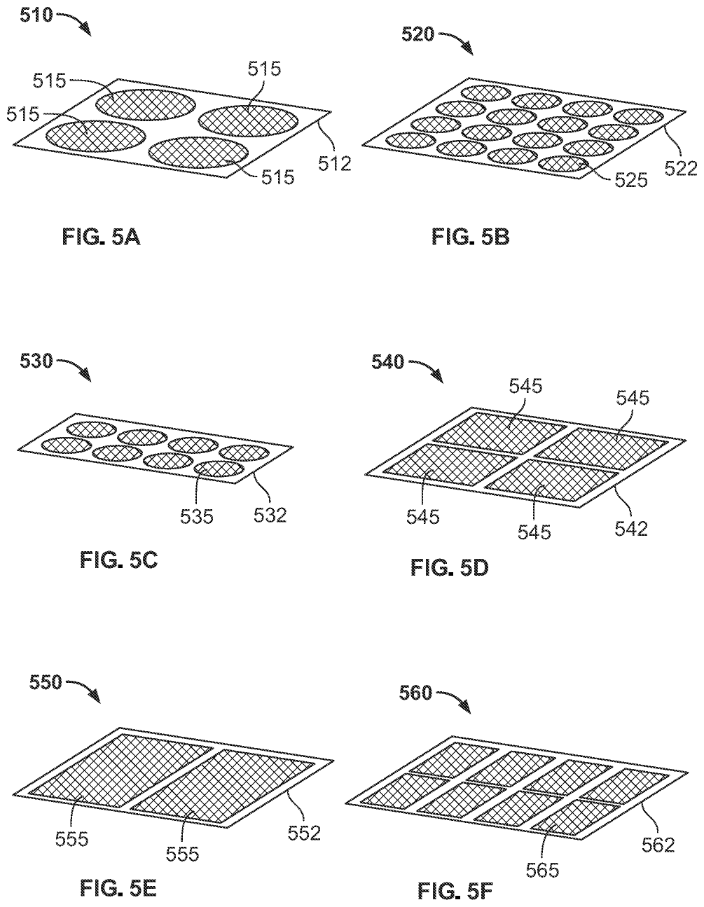

As explained above with regard to FIG. 2, the manufacturing system at 225 may mount subpanels to a carrier panel to form a panel upon which further operations are performed. FIGS. 5A-5F depict various examples of subpanel, panel, and hybrid panel configurations, which the manufacturing system may utilize and/or form at 225. Referring to FIG. 5A, a perspective view of a panel 510 is provided. The panel 510 may include four circular subpanels 515 such as wafer subpanels, reconstituted wafer subpanels, etc. mounted to a square carrier panel 512. Referring to FIG. 5B, a perspective view of another example panel 520 is shown. The panel 520 may include sixteen circular subpanels 525 such as wafer subpanels, reconstituted wafer subpanels, etc. mounted to a square carrier panel 522. A perspective view of another example panel 530 is shown in FIG. 5C. The panel 530 may include eight circular subpanels 535 such as wafer subpanels, reconstituted wafer subpanels, etc. mounted to a rectangular and non-square panel 532.

As discussed herein, the panels and their mounted subpanels may be square, rectangular, n-polygonal with n being an integer greater than two, etc. For example, a perspective view of such an example panel 540 is shown in FIG. 5D. The panel 540 may include four square subpanels 545 mounted to a square carrier panel 542. A perspective view of another example panel 550 is shown in FIG. 5E. The panel 550 may include two rectangular (e.g., non-square, or strip) subpanels 555 mounted to a square carrier panel 552. Referring to FIG. 5F, a perspective view of another example panel 560 is shown. The panel 560 may include eight rectangular (or square) subpanels 565 mounted to a rectangular (e.g., non-square) carrier panel 562.

As shown in the various panel examples 510, 520, 530, 540, 550, and 560, the subpanels may be arranged in a matrix (or row/column) configuration on the carrier panel. Such matrix configurations may include a same number of subpanels in the rows and columns, or may include a different number of subpanels in the rows and columns. In various implementations, panels may arrange subpanels in a non-matrix configuration. As such, the scope of this disclosure covers both matrix and non-matrix configurations. For example, subpanels may be arranged in a circular configuration, n-polygonal configuration with n being any integer greater than two, staggered configuration, etc.

Also, as shown in the various panel examples 510, 520, 530, 540, 550, and 560, the subpanels mounted to a particular carrier panel may all be identical or may be a same shape or size. The scope of this disclosure is not necessarily limited thereto. For example, subpanels of different shapes or sizes may be mounted to a same carrier panel. Also for example, subpanels of different types of dies (e.g., with the same or different size subpanel dimensions) may be mounted to a same carrier panel. Also, subpanels with different sizes or numbers of respective dies may be mounted to a same carrier panel.

Additionally, as shown in the various panel examples 510, 520, 530, 540, 550, and 560, the subpanels may be arranged on a carrier panel, such that the carrier panel extends laterally outward from the subpanels. For example, an outer perimeter region on the top side of the carrier panel may laterally surround the subpanels. Such an outer perimeter region on the top side of the carrier panel may be free of adhesive material. Such a configuration may be beneficial for a variety of reasons such as carrier panel handling, carrier panel securing, carrier panel alignment, inspection, processing uniformity, etc.

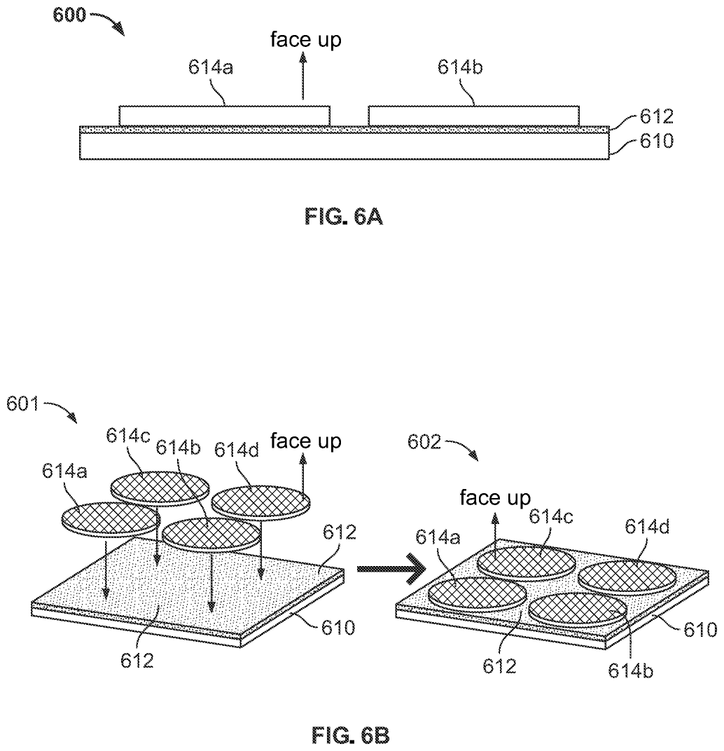

Again, as explained above with regard to FIG. 2, the manufacturing system at 225 may mount subpanels to a carrier panel to form a panel upon which further operations are performed. FIGS. 6A and 6B depict aspects of such panel formation. As shown, an example carrier panel 610 may be provided. As discussed herein, the carrier panel 610 may comprise any of a variety of materials. For example, the carrier panel 610 may comprise metal (e.g., stainless steel, etc.), glass, ceramic, etc. In an example implementation, the carrier panel 610 may comprise glass through which light (e.g., UV radiation) may efficiently pass to a light-releasable adhesive thereon such as glass or other material having a high transmittance at the relevant wavelengths, above 80%, above 90%, etc. In another example implementation, the carrier panel 610 or any carrier panel discussed herein may comprise a metal or other conductive material through which thermal energy may efficiently pass to a thermal-releasable adhesive thereon.

Note that the example carrier panel 610 or any example carrier panel discussed herein may be formed of a material that has a same or substantially the same (e.g., within 5%, within 10%, etc.) coefficient of thermal expansion (CTE) as the subpanels to be mounted to the carrier panel 610. Also for example, the example carrier panel 610 or any example carrier panel discussed herein may be formed of a material that has a CTE within 25% or 50% of the CTEs of the subpanels to be mounted to the carrier panel 610.

Per FIGS. 6A and 6B, the manufacturing system at 225 may form an adhesive material or adhesive layer 612 on the carrier panel 610. As discussed herein, the adhesive material 612 may comprise any of a variety of characteristics. For example, the adhesive material 612 may comprise a light-releasable adhesive, a thermal-releasable adhesive, a die-attach adhesive, a curable bonding agent, etc. As discussed herein, although the adhesive material 612 is shown covering an entire top side of the carrier panel 610, such coverage is not required. For example, a perimeter region on the top side of the carrier panel 610, or at one or more lateral or horizontal ends of the top side of the carrier panel 610, may remain free of the adhesive material 612. Such adhesive free regions may be beneficial for handling, securing, aligning, etc. the carrier panel 610 and/or subpanels.

The manufacturing system may form the adhesive material 612 in any of a variety of manners such as rolling on, printing, spraying one or multiple coats, applying or laminating a preformed adhesive tape or film, spin-coating, dipping, etc. In an example implementation, the adhesive material 612 is applied via a preformed adhesive sheet such as a tape or film that may be rolled on the top side of the carrier panel 610.

Per FIGS. 6A and 6B, the manufacturing system may form the adhesive material 612 on the carrier panel 610 prior to placing the subpanels 614a, 614b, 614c, and 614d on the carrier panel 610. Alternatively, the manufacturing system may individually form adhesive material 612 on the back sides of the subpanels 614a-614d instead of, or in addition to, forming adhesive material 612 on the carrier panel 610.

In the example shown in FIGS. 6A and 6B, after the adhesive material 612 is formed on the carrier panel 610, the manufacturing system may place or press the subpanels 614a-614d on the adhesive material 612, thus adhering the subpanels 614a-614d to the carrier panel 610. In various implementations, the manufacturing system may use vacuum lamination, clamping, or other force providing process to mount the subpanels 614a-614d to the adhesive material 612 and carrier panel 610.

As shown, the manufacturing system may mount the subpanels 614a-614d face-up such that front or active sides of the subpanel semiconductor dies are facing upward and/or interconnection structures of the subpanel semiconductor dies are facing upward. In general, the manufacturing system may position a side (e.g., a front side, an active side, a back side, inactive side, or other side) of the subpanel on which further processing is to be performed, face upward from the carrier panel 610.

In this example, the top side of the carrier panel 610 is entirely planar. However, the entire top side of the carrier panel 610 may not be planar in other implementations. For example, the carrier panel 610 may comprise apertures in or over which the subpanels 614a-614d are placed. Such apertures may extend entirely or only partially through the carrier panel 610. In some implementations, the carrier panel 610 may comprise cavities such as registration indentations, etc. in or over which the subpanels 614a-614d are placed. Such cavities may extend entirely or only partially through the carrier panel 610.

The discussion herein included numerous illustrative figures that showed various methods of manufacturing an electronic device, various apparatuses for performing such methods, and various electronic devices or portions thereof resulting from performing such methods. For illustrative clarity, such figures did not show all aspects of each of the example methods, apparatuses, or electronic devices. Any of the example methods, apparatuses, or electronic devices presented herein may share any or all characteristics with any or all of the other example methods, apparatuses, or electronic devices presented herein.

While the foregoing has been described with reference to certain aspects and examples, various changes may be made and equivalents may be substituted without departing from the scope of the disclosure. In addition, many modifications may be made to adapt a particular situation or material to the teachings of the disclosure without departing from its scope. Therefore, it is intended that the disclosure not be limited to the particular example(s) disclosed, but that the disclosure will include all examples falling within the scope of the appended claims.

What is claimed is:

1. An electronic device, comprising
a substrate comprising:
a dielectric layer comprising a dielectric layer top side, a dielectric layer bottom side, a dielectric layer lateral side between the dielectric layer top side and the dielectric layer lateral side, and a dielectric layer aperture that pass through the dielectric layer from the dielectric layer top side to the dielectric layer bottom side;
a seed layer on the dielectric layer bottom side, wherein the seed layer extends into the dielectric layer aperture toward the dielectric layer top side;
a conductive pattern on the seed layer, wherein the conductive pattern extends into the dielectric layer aperture toward the dielectric layer top side;
an external interconnect first structure comprising an external interconnect first structure top side coupled to the conductive pattern; and
a substrate encapsulant that surrounds and contacts the dielectric layer lateral side, a lateral side of the conductive pattern, and a lateral side of the external interconnect first structure; and
a semiconductor component comprising a component bottom side coupled to the dielectric layer top side and an interconnection structure electrically coupled to the conductive pattern via the seed layer.

2. The electronic device of claim 1, wherein the dielectric layer comprises a photo-definable dry film.

3. The electronic device of claim 1, wherein the dielectric layer comprises a dry film of dielectric material that is not photo-definable.

4. The electronic device of claim 1, wherein the dielectric layer has a loss tangent of 0.015 or less.

5. The electronic device of claim 1, wherein a thickness of the dielectric layer between the dielectric layer top side and the dielectric layer bottom side is greater than 20 μm.

6. The electronic device of claim 1, comprising a component encapsulant that surrounds and contacts a component lateral side of the semiconductor component.

7. The electronic device of claim 1, comprising a component encapsulant that surrounds and contacts a component top side and a component lateral side of the semiconductor component.

8. The electronic device of claim 1, wherein:
the conductive pattern comprises one or more electroplated conductive layers; and
the external interconnect first structure comprises one or more electroplated conductive layers.

9. The electronic device of claim 1, wherein the seed layer contacts the interconnection structure of the semiconductor component.

10. The electronic device of claim 1, wherein:
a width of the dielectric layer between opposite dielectric lateral sides is greater than a width of the semiconductor component between corresponding component lateral sides; and
the width of the dielectric layer between the opposite dielectric lateral sides is less than a width of the substrate between corresponding substrate lateral sides.

11. The electronic device of claim 1, wherein the substrate lacks a seed layer between the conductive pattern and the external interconnect first structure.

12. The electronic device of claim 1, comprising:
an external interconnect second structure coupled to a bottom side of the external interconnect first structure; and
wherein the substrate encapsulant laterally surrounds at least a portion of a lateral side of the external interconnect second structure.

13. The electronic device of claim 12, wherein:
the external interconnect first structure comprises a conductive stud; and
the external interconnect second structure comprises a solder ball.

14. A method comprising:
providing a first dielectric layer over a front side of a semiconductor component;
patterning the first dielectric layer to form a patterned first dielectric layer;
forming a seed layer over the patterned first dielectric layer;
electroplating a conductive pattern on the seed layer by applying current to the seed layer; and
electroplating an external interconnect first structure on the conductive pattern by applying current to the seed layer.

15. The method of claim 14, comprising:
providing a second dielectric layer on the seed layer;
patterning the second dielectric layer to form a patterned second dielectric layer on the seed layer prior to electroplating the conductive pattern;
providing a third dielectric layer on the conductive pattern and the patterned second dielectric layer; and
patterning the third dielectric layer to form a patterned third dielectric layer prior to electroplating the external interconnect first structure.

16. The method of claim 15, comprising:
removing the patterned second dielectric layer and the patterned third dielectric layer;
providing an external interconnect second structure on the external interconnect first structure; and
forming a substrate encapsulant that laterally surrounds at least a portion of the external interconnect first structure, a lateral side of the patterned first dielectric layer, and a portion of a lateral side of the external interconnect second structure.

17. The method of claim 15, comprising:
removing the patterned second dielectric layer and the patterned third dielectric layer;
forming a substrate encapsulant that surrounds and contacts a lateral side of the external interconnect first structure and a lateral side of the patterned first dielectric layer;
grinding a surface of the substrate encapsulant to expose the external interconnect first structure; and
providing an external interconnect second structure on the exposed external interconnect first structure.

18. The method of claim 14, wherein:
providing the first dielectric layer comprises laminating a dry film of the first dielectric layer over the front side of the semiconductor component; and
patterning the first dielectric layer comprises patterning the first dielectric layer without the aid of photoresist by:
radiating portions of the dry film; and
removing portions of the dry film to define the patterned first dielectric layer.

19. The method of claim 14, wherein:
providing the first dielectric layer comprises laminating a dry film over the front side of the semiconductor component; and
patterning the first dielectric layer comprises removing portions of the dry film to define the patterned first dielectric layer using laser ablation.

20. The method of claim 14, comprising:
providing a panel comprising subpanels, wherein each subpanel comprises semiconductor components encapsulated in a component encapsulant with front sides of the semiconductor components exposed at a top side of each subpanel; and
wherein providing the first dielectric layer over the front side of the semiconductor component comprises providing the first dielectric layer over the front sides of the semiconductor components exposed at the top side of each subpanel.
